(19) United States
(12) Patent Application Publication
(10) Pub. No.: US 2006/0067057 A1
(43) Pub. Date: Mar. 30, 2006

(54) Heat sink module

(75) Inventors: Cheng-Lai Shen, Taipei (TW); Chuan-Te Chang, Taipei (TW)

Correspondence Address: BIRCH STEWART KOLASCH & BIRCH, PO BOX 747, FALLS CHURCH, VA, 22040-0747, US

(73) Assignee: ASUSTeK COMPUTER INC.

(21) Appl. No.: 11/239,300

(22) Filed: Sep. 30, 2005

(30) Foreign Application Priority Data
Sep. 30, 2004 (TW) 093129729

(51) Int. Cl. H05K 7/20

(52) U.S. Cl. 361/709; 361/719; 165/104.33

(57) ABSTRACT

A heat sink module is used for a central processing unit (CPU). The CPU is located on a top surface of a circuit board. The heat sink module includes a heat conducting structure for conducting and radiating the heat of the CPU. The heat conducting structure goes via the circuit board and extends to a bottom surface of the circuit board.

### BACKGROUND OF THE INVENTION

1. Field of Invention

The invention relates to a heat sink module and, in particular, to a heat sink module used for a central processing unit (CPU).

2. Related Art

A Central Processing Unit (CPU) is the central nerve for a computer to process information and the whole system performance is largely dependant on the performance of the CPU. Accordingly, the higher frequency and the higher performance of the CPU surely lead the market trend.

The CPU having high frequency and high speed produces more heat and the inside of the computer system thus gets higher temperature. Accordingly, the CPU stability is seriously threatened. To ensure the normal operation of the CPU, it is necessary to radiate the heat promptly. Therefore, a heat sink 12 is provided on the surface of a CPU 11 in a conventional CPU heat sink structure 1. The heat sink 12 includes a base 121 and a plurality of heat sink fins 122 for passively conducting out the heat produced by the CPU 11. Besides, a fan 13 can further be located on the heat sink 12. In this case, the heat can be actively conducted from the surface of the CPU 11 to other places by the airflow produced by the fan 13.

Regarding to the conventional CPU heat sink structure 1, the heat produced by the CPU 11 is radiated through the heat sink fins 122 combined with the fan 13. In this single pathway, if the CPU 11 produces more heat, only increasing the height of the heat sink fins 122 for providing larger heat radiating area and increasing the rotation speed of the fan 13 can improve the heat dissipation efficiency. However, if the height of the fins 122 increases, the dimension of the product also increases. In addition, if the rotation speed of the fan 13 increases, the noise problem accordingly occurs. As a result, the conventional way for decreasing the temperature of the CPU 11 will lead to problems of space insufficiency and noise.

It is therefore an important subject of the invention to provide a heat sink module that can solve the above-mentioned problems caused by the single heat radiating pathway.

### SUMMARY OF THE INVENTION

In view of the foregoing, the invention is to provide a heat sink module that possesses an additional heat radiating pathway for increasing the heat dissipation efficiency of a central processing unit (CPU).

To achieve the above, a heat sink module of the invention is used for a CPU, which is located on a top surface of a circuit board. The heat sink module includes a heat conducting structure, which goes via the circuit board and extends to a bottom surface of the circuit board, for conducting and radiating heat of the CPU.

In addition, to achieve the above, a heat sink module of the invention is used for a CPU, which is located on a CPU socket module of a top surface of a circuit board. The heat sink module includes a heat conducting structure, which connects to the CPU socket module, goes via the circuit board and extends to a bottom surface of the circuit board, for conducting and radiating heat of the CPU.

Furthermore, to achieve the above, a heat sink module of the invention is used for a surface of a CPU, which is located on a top surface of a circuit board. The heat sink module includes a heat dissipating plate and a heat conducting structure. The heat dissipating plate includes a base and a plurality of fins, which are located on a surface of the base. The heat conducting structure goes via the circuit board and extends from the heat dissipating plate to a bottom surface of the circuit board for conducting and radiating heat of the CPU.

As mentioned above, the heat sink module of the invention goes via the circuit board and extends to the heat conducting structure located on the bottom surface of the circuit board for conducting the heat produced by the CPU to other places, such as the heat dissipating plate positioned on the bottom surface of the circuit board. Comparing to the conventional technology, the heat sink module for the CPU of the invention provides an additional pathway for radiating heat except for using the heat sink fins and fans. Thus, it increases the heat dissipation efficiency of the CPU and increases the stability of the system. Besides, since the conducting structure provides the CPU another way for radiating heat, the heat dissipation efficiency can be increased without the fan of higher rotation speed or the fins of higher height. Therefore, the noise produced by the fan of high rotation speed and the increased space cost caused by the larger dimension fins are avoided.

### BRIEF DESCRIPTION OF THE DRAWINGS

The invention will become more fully understood from the detailed description given herein below illustration only, and thus is not limitative of the present invention, and wherein:

FIG. 1 is a schematic illustration showing the conventional conducting structure of the central processing unit;

FIG. 2 is a schematic illustration showing a heat sink module according to an embodiment of the invention;

FIG. 3 is a sectional illustration along A-A′ line in FIG. 2 showing a heat sink module according to an embodiment of the invention;

FIG. 4 is a schematic illustration showing a heat sink module according to a second embodiment of the invention;

FIG. 5 is a schematic illustration showing a CPU socket module of the heat sink module according to a second embodiment of the invention;

FIG. 6 is another schematic illustration showing a heat sink module according to a second embodiment of the invention;

FIG. 7 is a sectional illustration along B-B′ line in FIG. 6 showing a heat sink module of according to a second embodiment of the invention;

FIG. 8 is still another schematic illustration showing a heat sink module according to a second embodiment of the invention;

FIG. 9 is still another schematic illustration showing a heat sink module according to a second embodiment of the invention, wherein the heat sink module includes a pad;

FIG. 10 is a sectional illustration along C-C′ line in FIG. 9 showing a heat sink module according to a second embodiment of the invention; and

FIG. 11 is a schematic illustration showing a heat sink module according to a third embodiment of the invention.

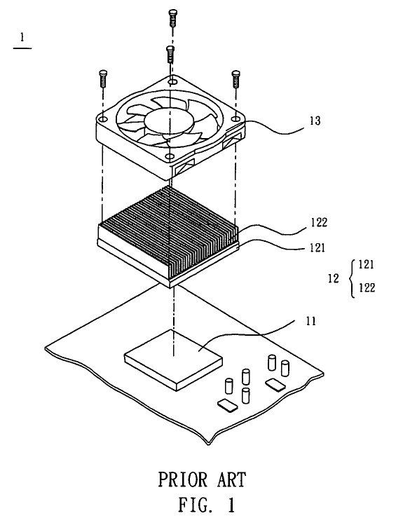

### DETAILED DESCRIPTION OF THE INVENTION

The present invention will be apparent from the following detailed description, which proceeds with reference to the accompanying drawings, wherein the same references relate to the same elements.

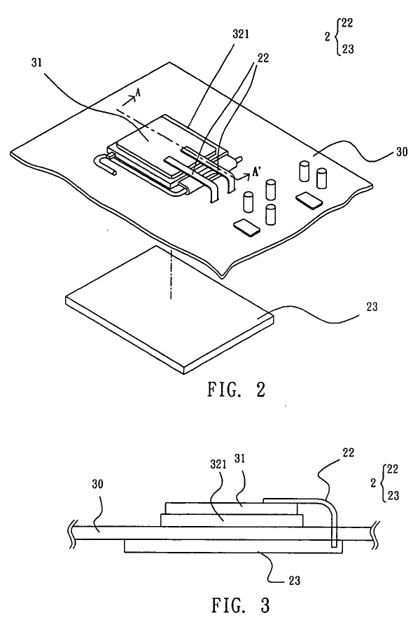

Firstly, please refer to FIG. 2 to illustrate a heat sink module according to a first preferred embodiment of the invention.

In this embodiment, a heat sink module 2 is utilized for a CPU (central processing unit) 31. The CPU 31 is located on a socket 321 such as a DIP socket, and the socket is installed on the top surface of a circuit board 30. The CPU is then indirectly located on the top surface of the circuit board 30. The pins of the CPU 31 are directly inserted into the holes of the socket 321 to electrically connect to the circuit board 30.

With reference to FIG. 3, the heat sink module 2 includes a heat conducting structure 22. The heat conducting structure 22 goes via the circuit board 30 and extends to a bottom surface of the circuit board 30. In this embodiment, the heat conducting structure 22 connects to the CPU 31 and the number of the heat conducting structure 22 varies with the need in practice. In the present embodiment, there are, for example, two heat conducting structures 22 provided in the heat sink module 2. The heat conducting structure 22 can be a screw, a heating pipe, a copper boss or an aluminum boss for conducting and radiating the heat of the CPU 31.

As shown in FIG. 2 and FIG. 3, the heat sink module 2 of this embodiment further includes a heat dissipating plate 23, which connects to the heat conducting structure 22. The heat dissipating plate 23 is located on the bottom surface of the circuit board 30. In this case, the heat dissipating plate 23 can cover the bottom surface of the circuit board 30, so that an extra space for accommodating the heat dissipating plate 23 is unnecessary. Thus, the heat produced by the CPU 31 can be conducted from the CPU 31 to the heat conducting structure 22, and then to the heat dissipating plate 23 on the bottom surface of the circuit board 30. To be noted, the size of the heat dissipating plate 23 can be adjusted according to the actual need.

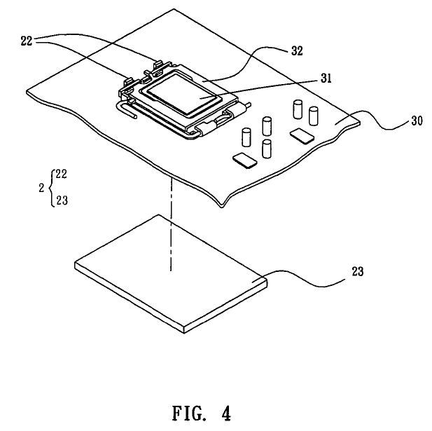

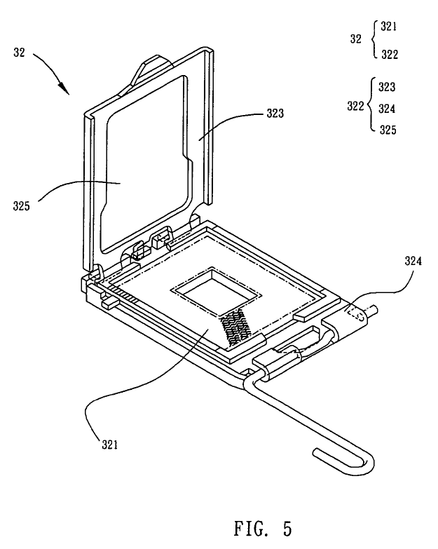

Next, please refer to FIG. 4 and FIG. 5 to illustrate a heat sink module 2 according to a second preferred embodiment of the invention.

The heat sink module 2 includes a heat conducting structure 22 and is utilized for a CPU 31 for conducting and radiating heat of the CPU 31. The CPU 31 is located on a CPU socket module 32.

Referring to FIG. 4 and FIG. 5, in this embodiment, the CPU socket module 32 is located on the circuit board 30 and includes a socket 321 and a fastening clip 322. The fastening clip 322 is made of a conducting material such as a conducing metal. In more details, the fastening clip 322 includes a cover 323 having an opening 325 and a base 324. The socket 321 is accommodated in the base 324, and the cover 323 is pivoted on the base 324. The CPU electrically connects to the elastic slice pins of the socket 321, and then the cover 323 of the clip 322 is enclosed. In this case, the cover 323 directly connects to the CPU 31, and a partial surface of the CPU 31 is exposed through the opening 325.

As shown in FIG. 4, the heat conducting structure 22 connects to the CPU socket module 32, goes via the circuit board 30 and extends to the bottom surface of the circuit board 30. The number of the heat conducting structures 22 varies according to the actual need. In this embodiment, the heat sink module 2 includes, for example, two heat conducting structures 22. The heat conducting structure 22 can be a screw, a heat pipe, a copper boss, an aluminum boss or other conducting materials. In this case, the heat conducting structure 22 connecting to the CPU socket module 32 can conduct the heat from the CPU 31 to the bottom surface of the circuit board 30. Thus, the large surface area of the circuit board 30 can be utilized to provide a better heat dissipation.

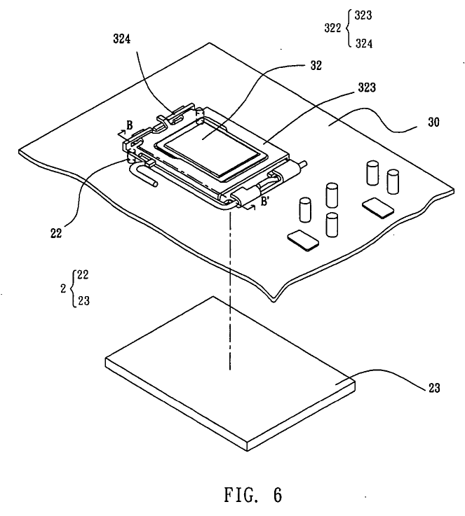

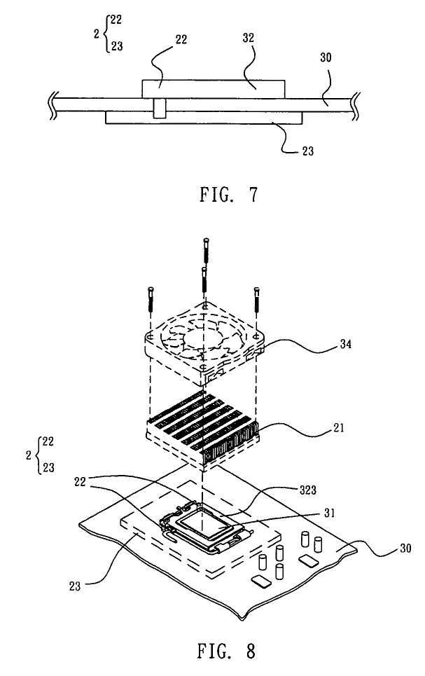

Referring to FIG. 6 and FIG. 7, the heat conducting structure 22 connects to the back side of the fastening clip 322 of the CPU socket module 32, goes via the circuit board 30 and extends to the bottom surface of the circuit board 30. Thus, the heat of the CPU 31 can be conducted to the heat conducting structure 22 through to the fastening clip 322 directly connecting to the CPU 31. FIG. 7 shows parts of the sectional illustration of the FIG. 6. The heat conducting structure 22 and the CPU socket module 32 can be integrally formed.

As shown in FIG. 6 and FIG. 8, the heat sink module 2 may further include a heat dissipating plate 23 connecting to the heat conducting structure 22. The heat dissipating plate 23 is located on the bottom surface of the circuit board 30 and covers the bottom surface of the circuit board 30, so that an extra space for accommodating the heat dissipating plate 23 is unnecessary. Thus, the heat produced by the CPU 31 can be conducted to the fastening clip 322, the conducting structure 22, and the heat dissipating plate 23 on the bottom surface of the circuit board 30 in sequence. The size of the heat dissipating plate 23 can be adjusted according to the actual need. Therefore, the heat produced by the CPU 31 can be conducted to the heat sink 12 and the fan 34 in one pathway (as shown in FIG. 8), and in the embodiment, the invention further utilizes the heat conducting structure 22 to conduct heat to the heat dissipating plate 23 in another pathway.

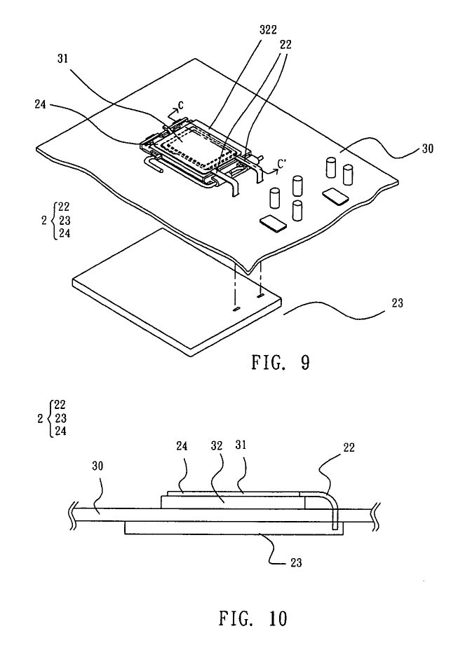

Further, as shown in FIG. 9 and FIG. 10, the heat sink module 2 may further include a pad 24, which is located on the CPU socket module 32. The pad 24 can connect directly to the CPU 31 through the opening 325 of the fastening clip 322 (shown in FIG. 5). Accordingly, the heat produced by the CPU 31 can be conducted to the pad 24. In this case, the pad 24 is made of conducting materials, such as copper foil, aluminum sheet or other conducting materials. The heat conducting structure 22 can be connected with the pad 24. For example, the heat conducting structure 22 can extend from the pad 24 via the circuit board 30 to connect with the heat dissipating plate 23. In the practical process, the pad 24 and the heat conducting structure 22 can also be integrally formed. Thus, the heat conducting structure 22 cooperated with the pad 24 can conduct the heat produced by the CPU 31 to the heat dissipating plate 23 located on the other side of the circuit board 30 and provide an additional pathway to conduct the heat.

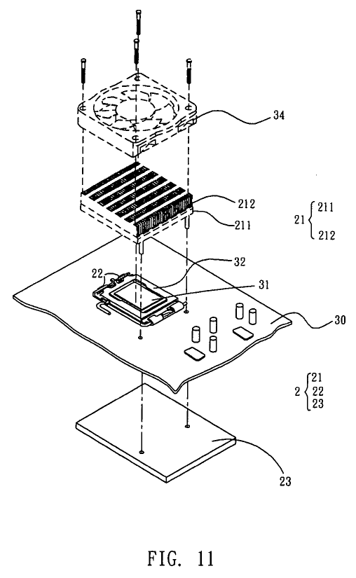

Then, please refer to the FIG. 11 to illustrate a heat sink module 2 according to a third preferred embodiment of the invention.

In this embodiment, the heat sink module 2 is utilized for the surface of the CPU 31. The CPU 31 is located on the top surface of the circuit board 30. The heat sink module 2 includes a heat sink 21 and a heat conducting structure 22.

The heat sink 21 includes a base 211 and a plurality of fins 212 located on the surface of the base 211.

The heat conducting structure 22 extends from the heat sink 21 to the bottom surface of the circuit board 30 via the circuit board 30 for conducting and radiating the heat produced by the CPU 31. The heat conducting structure 22 can be a screw, a heat pipe, a copper boss or an aluminum boss. Surely, the heat conducting structure 22 and the heat sink 21 can be integrally formed. Thus, using the heat conducting structure 22 extended from the heat sink 21, the heat produced by the CPU 31 can be conducted from the heat conducting structure 22 to the heat sink 21. Accordingly, an additional heat conduction pathway is provided.

With reference to FIG. 11, the heat sink module 2 of the embodiment further includes a heat dissipating plate 23 connecting with the heat conducting structure 22. In this case, the heat dissipating plate 23 is located on the bottom surface of the circuit board 30. Since the heat dissipating plate 23 covers the bottom surface of the circuit board 30, the extra space for accommodating it is unnecessary. Therefore, the heat produced by the CPU 31 can be conducted from the CPU 31 to the CPU socket module 32 and the heat conducting structure 22, and then conducted to the heat dissipating plate 23 on the bottom surface of the circuit board 30. The dimension of the heat dissipating plate 23 can vary with actual needs to increase the heat dissipation efficiency of the CPU 31.

In summary, the heat sink module of the invention uses the heat conducting structure, which goes via the circuit board and extends to the bottom surface of the circuit board, to conduct the heat produced by the CPU to other places such as the heat dissipating plate located on the bottom surface of the circuit board. Comparing the conventional technology with the invention, the heat sink module of the invention providing another pathway of radiating heat is other than the prior art of utilizing heat sink and fan. Thus, the CPU is able to conduct heat in multi-pathway so as to enhance the heat dissipation efficiency of the CPU and increase the stability of the system. In addition, because the heat conducting structure provides an additional pathway to conduct heat of the CPU, neither the fan of higher rotation speed nor the fins of higher height is needed to increase the heat dissipation efficiency. Thus, the noise produced by the fans and the space cost increase due to the disposition of the larger fins are avoided.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A heat sink module for a central processing unit (CPU) locating on a top surface of a circuit board, comprising:
a heat conducting structure going via the circuit board and extending to a bottom surface of the circuit board for conducting and radiating heat of the CPU.

2. The heat sink module according to claim 1, further comprising:
a heat dissipating plate connecting to the heat conducting structure and locating on the bottom surface of the circuit board.

3. The heat sink module according to claim 1, wherein the heat conducting structure is connected to the CPU.

4. The heat sink module according to claim 1, wherein the CPU is located on a CPU socket module comprising a socket and a fastening clip.

5. The heat sink module according to claim 4, wherein the fastening clip comprises a base and a cover, the cover is pivoted to the base, and the heat conducting structure extends to and connects to the base.

6. The heat sink module according to claim 5, further comprising:
a pad located on the cover and connected to the heat conducting structure.

7. The heat sink module according to claim 1, wherein the heat conducting structure is one of a screw, a heat pipe, a cupper boss and an aluminum boss.

8. A heat sink module for a central processing unit (CPU) locating on a CPU socket module of a top surface of a circuit board, the heat sink module comprising:
a heat conducting structure connecting to the CPU socket module, going via the circuit board, and extending to a bottom surface of the circuit board for conducting and radiating heat of the CPU.

9. The heat sink module according to claim 8, further comprising:
a heat dissipating plate connecting to the heat conducting structure and locating on the bottom surface of the circuit board.

10. The heat sink module according to claim 8, wherein the CPU socket module comprises a socket and a fastening clip.

11. The heat sink module according to claim 10, wherein the fastening clip comprises a base and a cover, the cover is pivoted to the base, and the heat conducting structure extends to and connects to the base.

12. The heat sink module according to claim 8, wherein the heat conducting structure is one of a screw, a heat pipe, a cupper boss and an aluminum boss.

13. The heat sink module according to claim 8, further comprising:
a pad covering the CPU socket module and connecting to the heat conducting structure.

14. A heat sink module for a surface of a central processing unit (CPU) locating on a top surface of a circuit board, comprising:
a heat sink comprising a base and a plurality of fins locating on a surface of the base; and
a heat conducting structure going via the circuit board and extending from the heat sink to a bottom surface of the circuit board for conducting and radiating heat of the CPU.

15. The heat sink module according to claim 14, wherein the heat conducting structure is one of a screw, a heat pipe, a cupper boss and an aluminum boss.

16. The heat sink module according to claim 14, further comprising:
a heat dissipating plate connecting to the heat conducting structure and locating on the bottom surface of the circuit board.
